(19) United States
(12) Patent Application Publication
(10) Pub. No.: US 2026/0068212 A1
(43) Pub. Date: Mar. 5, 2026

(54) TRANSISTOR STRUCTURE AND FABRICATION METHOD THEREOF

(71) Applicant: United Microelectronics Corp., Hsin-Chu City (TW)

(72) Inventors: Ming-Hua Tsai, Tainan City (TW); Ming-Hsiang Tu, Tainan City (TW); Chin-Chia Kuo, Tainan City (TW); Chun-Lin Chen, Tainan City (TW); Chun-Wen Cheng, New Taipei City (TW); Ya-Hsin Huang, Tainan City (TW); Yung-Fang Yang, Chiayi City (TW); Chiu-Te Lee, Hsinchu County (TW); Shih-Chieh Hsu, New Taipei City (TW)

(73) Assignee: United Microelectronics Corp., Hsin-Chu City (TW)

(21) Appl. No.: 18/898,704

(22) Filed: Sep. 27, 2024

(30) Foreign Application Priority Data
Sep. 2, 2024 (TW) 113133029

(51) Int. Cl. H01L 29/78; H01L 29/06; H01L 29/423; H01L 29/66

(52) U.S. Cl. CPC H10D 30/601; H10D 30/0227; H10D 62/116; H10D 62/126; H10D 64/517

(57) ABSTRACT

A transistor structure includes a substrate and an active area defined by a trench isolation region on the substrate. The active area includes a source region, a drain region spaced apart from the source region, and a channel region between the source region and the drain region. A gate is disposed on the channel region. The gate has a gate length that is in parallel with a source-to-drain direction and a gate width that is smaller than a width of the active area.

### BACKGROUND OF THE INVENTION

### 1. Field of the Invention

The present invention relates to the field of semiconductor technology, and in particular to a medium-voltage transistor structure and a manufacturing method thereof.

### 2. Description of the Prior Art

As known in the art, transistors are formed on active areas that are surrounded by an STI structure. Due to the wet etching process used to remove the nitride masking layer and/or pad oxide, divots may be formed within an upper surface of the STI structure. Such divots adversely affect electrical behavior of transistors. For example, during fabrication of a transistor, a conductive gate material may be filled into the divots within an STI structure, causing the conductive gate material to have sharp edges that increase an electric field. The increased electrical field changes a threshold voltage of the transistor, which is also known as the kink effect.

### SUMMARY OF THE INVENTION

It is one object of the present invention to provide an improved transistor structure and a manufacturing method thereof to solve the deficiencies or shortcomings of the existing technology.

One aspect of the invention provides a transistor structure including a substrate; an active area defined by a trench isolation region on the substrate, wherein the active area comprises a source region, a drain region spaced apart from the source region, and a channel region between the source region and the drain region; a gate disposed on the channel region, wherein the gate has a gate length that is in parallel with a source-to-drain direction and a gate width that is smaller than a width of the active area; and a gate dielectric layer between the active area and the gate.

According to some embodiments, the gate does not overlap with the trench isolation region, and wherein the gate length is shorter than a length of the gate dielectric layer in the source-to-drain direction.

According to some embodiments, the gate is metal gate.

According to some embodiments, the gate has a first side edge distanced from an adjacent first side of the active area by a first margin.

According to some embodiments, the first margin is equal to or greater than 30 nm.

According to some embodiments, the gate has a second side edge that is opposite to the first side edge, and wherein the second side edge is distanced from an adjacent second side of the active area by a second margin.

According to some embodiments, the second margin is equal to or greater than 30 nm.

According to some embodiments, the gate has an H-shaped layout and the gate has rounded corners when viewed from above.

According to some embodiments, the transistor structure further includes at least one gate contact disposed on the gate, wherein the at least one gate contact is disposed directly above the channel region.

According to some embodiments, the transistor structure further includes a source contact disposed on the source region; and a drain contact disposed on the drain region.

Another aspect of the invention provides a method for forming a transistor structure. A substrate is prepared. An active area defined by a trench isolation region is formed on the substrate. The active area includes a source region, a drain region spaced apart from the source region, and a channel region between the source region and the drain region. A gate is formed on the channel region. The gate has a gate length that is in parallel with a source-to-drain direction and a gate width that is smaller than a width of the active area. A gate dielectric layer is formed between the active area and the gate.

According to some embodiments, the gate does not overlap with the trench isolation region, and wherein the gate length is shorter than a length of the gate dielectric layer in the source-to-drain direction.

According to some embodiments, the gate is metal gate.

According to some embodiments, the gate has a first side edge distanced from an adjacent first side of the active area by a first margin.

According to some embodiments, the first margin is equal to or greater than 30 nm.

According to some embodiments, the gate has a second side edge that is opposite to the first side edge, and the second side edge is distanced from an adjacent second side of the active area by a second margin.

According to some embodiments, the second margin is equal to or greater than 30 nm.

According to some embodiments, the gate has an H-shaped layout and the gate has rounded corners when viewed from above.

According to some embodiments, the method further includes the step of forming at least one gate contact on the gate, wherein the at least one gate contact is disposed directly above the channel region.

According to some embodiments, the method further includes the steps of forming a source contact on the source region; and forming a drain contact on the drain region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic layout diagram of a transistor structure according to an embodiment of the present invention.

FIG. 2 is a sectional view taken along line I-I′ in FIG. 1.

FIG. 3 is a sectional view taken along line II-II′ in FIG. 1.

FIG. 4 is a schematic layout diagram of a transistor structure according to another embodiment of the present invention

FIG. 5 is a schematic layout diagram of a transistor structure according to still another embodiment of the present invention.

FIG. 6 is a flow chart illustrating a method of forming a transistor structure.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

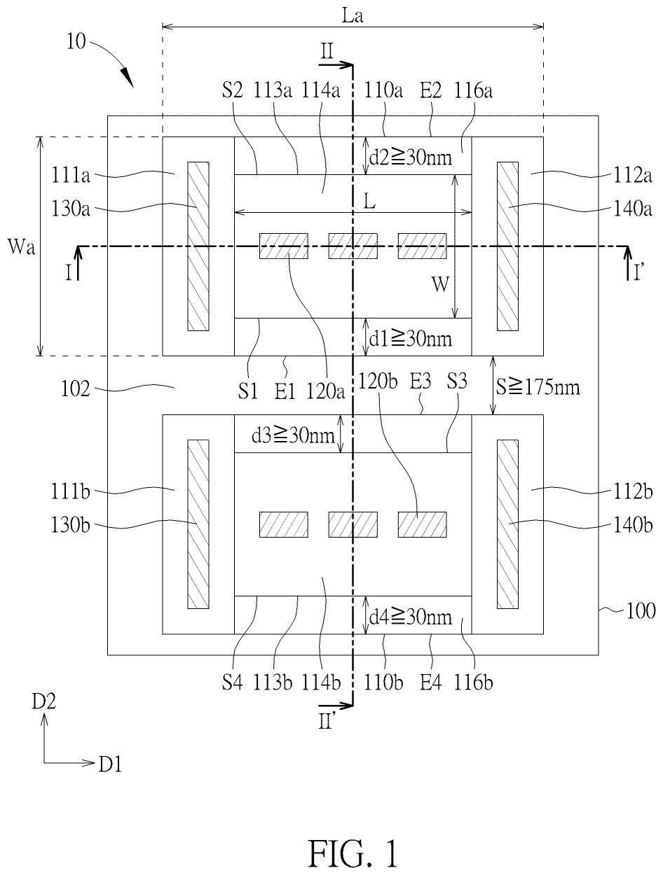

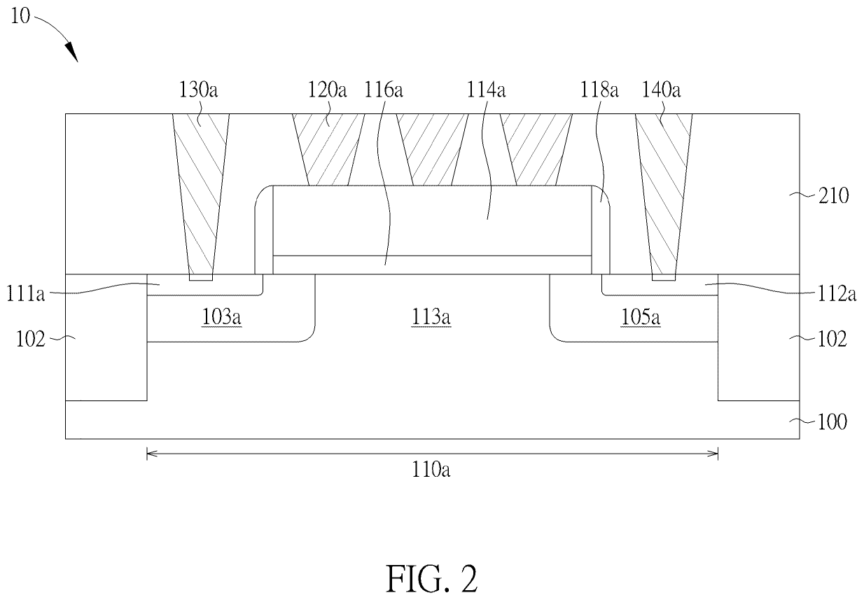

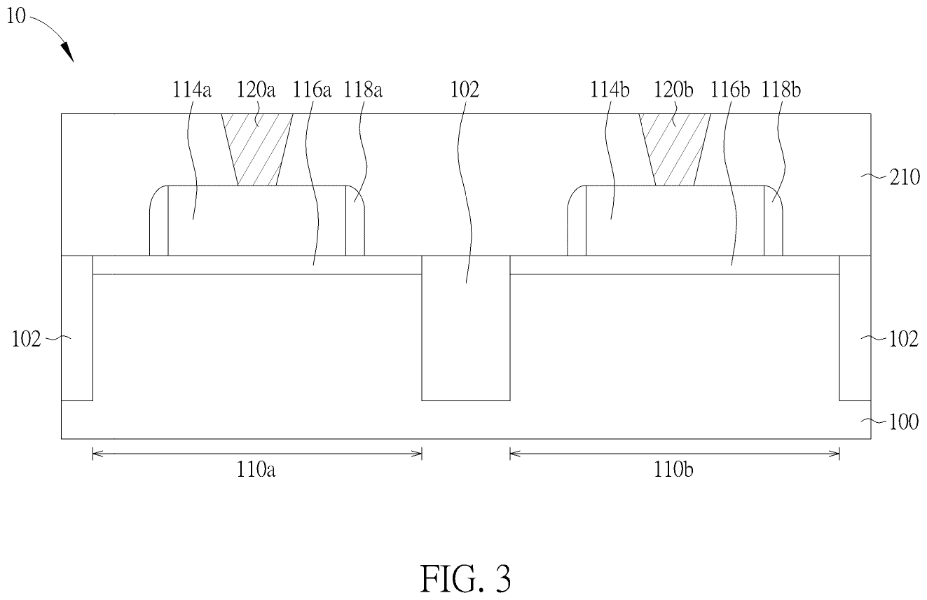

Please refer to FIG. 1 to FIG. 3. FIG. 1 is a schematic layout diagram of a transistor structure 10 according to an embodiment of the present invention. FIG. 2 is a sectional view taken along line I-I′ in FIG. 1. FIG. 3 is a sectional view taken along line II-II′ in FIG. 1. As shown in FIG. 1 to FIG. 3, the transistor structure 10 includes a substrate 100, for example, a P-type silicon substrate. According to an embodiment of the present invention, a trench isolation region 102 and active areas 110a and 110b defined by the trench isolation region 102 are formed on the substrate 100. It is understood that the substrate 100 may include a plurality of active areas. For the sake of simplicity, only two active areas are illustrated in the figures. According to an embodiment of the present invention, the active areas 110a and 110b are rectangular areas of equal size, with a length La and a width Wa. According to an embodiment of the present invention, the spacing S between the active areas 110a and 110b is, for example, equal to or greater than 175 nm.

According to an embodiment of the present invention, the active area 110a includes a source region 111a, a drain region 112a spaced apart from the source region 111a, and a channel region 113a located between the source region 111a and the drain region 112a. According to an embodiment of the present invention, the source region 111a and the drain region 112a may be N-type doped regions, but are not limited thereto. According to an embodiment of the present invention, the source region 111a and the drain region 112a may be formed in the lightly doped drain regions 103a and 105a, respectively.

According to an embodiment of the present invention, a gate 114a is provided on the channel region 113a, wherein the gate 114a has a gate length L parallel to the first direction D1 (source to drain direction). In the second direction D2, the gate width W of the gate 114a is smaller than the width Wa of the active area 110a. The first direction D1 and the second direction D2 may be orthogonal to each other. According to an embodiment of the present invention, a gate dielectric layer 116a is provided between the active area 110a and the gate 114a. According to an embodiment of the present invention, the gate 114a is a metal gate.

According to an embodiment of the present invention, the active area 110b includes a source region 111b, a drain region 112b spaced apart from the source region 111b, and a channel region 113b located between the source region 111b and the drain region 112b. A gate 114b is provided on the channel region 113b, wherein the gate 114b also has a gate length L parallel to the first direction D1 (source to drain direction). In the second direction D2, the gate width W of the gate 114b is smaller than the width Wa of the active area 110b. According to an embodiment of the present invention, a gate dielectric layer 116b is provided between the active area 110b and the gate 114b. According to an embodiment of the present invention, the gate 114b is a metal gate.

According to an embodiment of the present invention, when viewed from top to bottom, neither the gate 114a nor the gate 114b overlaps the trench isolation region 102. In other words, in the second direction D2, the gate 114a and the gate 114b are both retracted inward by a predetermined distance to prevent the gates 114a and 114b from extending into the trench isolation region 102 in the second direction D2.

According to an embodiment of the present invention, as shown in FIG. 1, the gate 114a has a sidewall S1, which is spaced from the side E1 of the active area 110 a by a margin d1. According to an embodiment of the present invention, for example, the margin d1 is equal to or greater than 30 nm. According to an embodiment of the present invention, the gate 114a has a sidewall S2 opposite to the sidewall S1, and the sidewall S2 is spaced from the side E2 of the active area 110a by a margin d2. The side E1 of the active area 110a may be parallel to the side E2. According to an embodiment of the present invention, for example, the margin d2 is equal to or greater than 30 nm.

According to an embodiment of the present invention, likewise, the gate 114b has a sidewall S3 that is spaced apart from the side E3 of the active area 110b by a margin d3. According to an embodiment of the present invention, for example, the margin d3 is equal to or greater than 30 nm. According to an embodiment of the present invention, the gate 114a has a sidewall S4 opposite to the sidewall S3, and the sidewall S4 is spaced from the side E4 of the active area 110a by a margin d4. The side E3 of the active area 110a may be parallel to the side E4. According to an embodiment of the present invention, for example, the margin d4 is equal to or greater than 30 nm.

According to an embodiment of the present invention, the transistor structure 10 further includes: a gate contact 120a disposed on the gate 114a, a gate contact 120b disposed on the gate 114b. The gate contact 120a is disposed directly above the channel region 113a and the gate contact 120b is disposed directly above channel region 113b.

According to an embodiment of the present invention, the transistor structure 10 further includes: a source contact 130a disposed on the source region 111a, a drain contact 140a disposed on the drain region 112a, a source contact 130b disposed on the source region. 111b, and drain contact 140b is disposed on drain region 112b.

According to an embodiment of the present invention, the transistor structure 10 may further include a dielectric layer 210, such as a silicon oxide layer, covering the source region 111a, the gate 114a, the drain region 112a, the source region 111b, the gate 114b, the drain region 112b, and the trench isolation region 102. The gate contacts 120a and 120b, the source contacts 130a and 130b, and the drain contacts 140a and 140b are formed in dielectric layer 210.

According to an embodiment of the present invention, a spacer 118a may be formed on the sidewall of the gate 114a, and a spacer 118b may be formed on the sidewall of the gate 114b. According to an embodiment of the present invention, for example, the spacers 118a and 118b may include a silicon nitride spacer, but are not limited thereto.

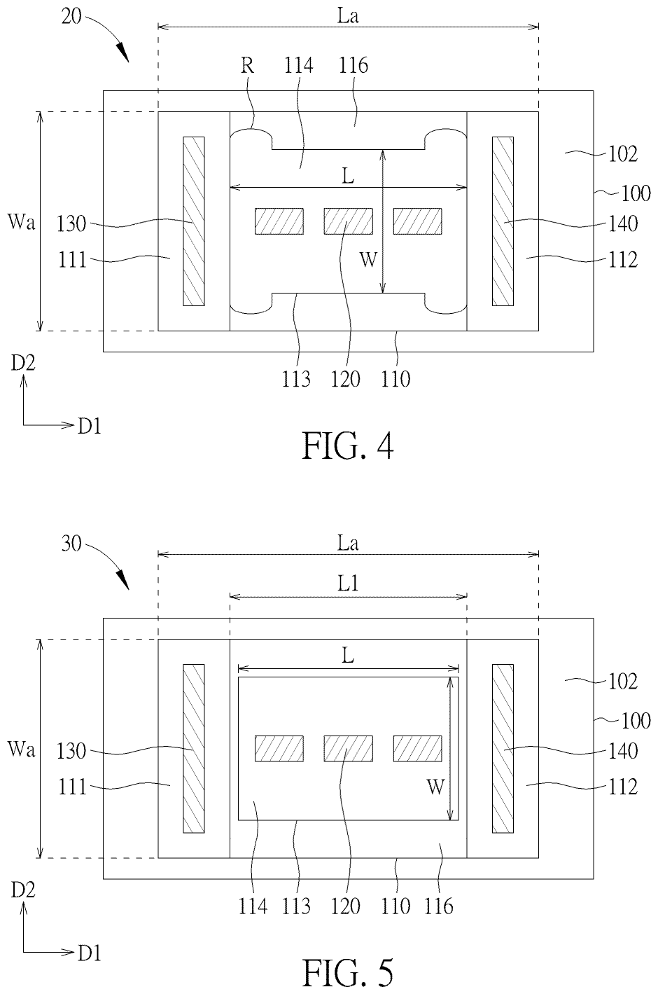

FIG. 4 is a schematic layout diagram of a transistor structure 20 according to another embodiment of the present invention, wherein like regions, layers or elements are designated by like numeral numbers or labels. As shown in FIG. 4, likewise, the transistor structure 20 includes a substrate 100, for example, a P-type silicon substrate. According to an embodiment of the present invention, a trench isolation region 102 and an active area 110 defined by the trench isolation region 102 are formed on the substrate 100. According to an embodiment of the present invention, the active area 110 has a length La and a width Wa.

According to an embodiment of the present invention, the active area 110 includes a source region 111, a drain region 112 spaced apart from the source region 111, and a channel region 113 located between the source region 111 and the drain region 112. According to an embodiment of the present invention, the source region 111 and the drain region 112 may be N-type doped regions.

According to an embodiment of the present invention, a gate 114 is provided on the channel region 113, wherein the gate 114 has a gate length L parallel to the first direction D1 (source-to-drain direction). According to an embodiment of the present invention, the gate 114 has an H-shaped layout, and has a rounded corner R when viewed from above. In the second direction D2, the gate width W of the gate 114 is smaller than the width Wa of the active area 110. According to an embodiment of the present invention, a gate dielectric layer 116 is provided between the active area 110 and the gate 114. According to an embodiment of the present invention, the gate 114 is a metal gate. According to an embodiment of the present invention, the gate 114 does not overlap with the trench isolation region 102. In other words, in the second direction D2, the gate 114 retracts inward by a predetermined distance.

According to an embodiment of the present invention, the transistor structure 20 further includes: a gate contact 120 disposed on the gate 114, wherein the gate contact 120 is disposed directly above the channel region 113. According to an embodiment of the present invention, the transistor structure 20 further includes: a source contact 130 disposed on the source region 111, and a drain contact 140 disposed on the drain region 112.

FIG. 5 is a schematic layout diagram of a transistor structure 30 according to another embodiment of the present invention, wherein like regions, layers or elements are designated by like numeral numbers or labels. As shown in FIG. 5, likewise, the transistor structure 30 includes a substrate 100, for example, a P-type silicon substrate. According to an embodiment of the present invention, a trench isolation region 102 and an active area 110 defined by the trench isolation region 102 are formed on the substrate 100. According to an embodiment of the present invention, the active area 110 has a length La and a width Wa.

According to an embodiment of the present invention, the active area 110 includes a source region 111, a drain region 112 spaced apart from the source region 111, and a channel region 113 located between the source region 111 and the drain region 112. According to an embodiment of the present invention, the source region 111 and the drain region 112 may be N-type doped regions.

According to an embodiment of the present invention, a gate 114 is provided on the channel region 113, wherein the gate 114 has a gate length L parallel to the first direction D1 (source-to-drain direction). In the second direction D2, the gate width W of the gate 114 is smaller than the width Wa of the active area 110. According to an embodiment of the present invention, a gate dielectric layer 116 is provided between the active area 110 and the gate 114. According to an embodiment of the present invention, the gate length L is shorter than the length L1 of the gate dielectric layer 116 in the first direction D1. In other words, both ends of the gate dielectric layer 116 in the first direction D1 are not covered by the gate 114. According to an embodiment of the present invention, the gate 114 is a metal gate. According to an embodiment of the present invention, the gate 114 does not overlap with the trench isolation region 102. In other words, in the second direction D2, the gate 114 retracts inward by a predetermined distance.

According to an embodiment of the present invention, the transistor structure 30 further includes: a gate contact 120 disposed on the gate 114, wherein the gate contact 120 is disposed directly above the channel region 113. According to an embodiment of the present invention, the transistor structure 20 further includes: a source contact 130 disposed on the source region 111, and a drain contact 140 disposed on the drain region 112.

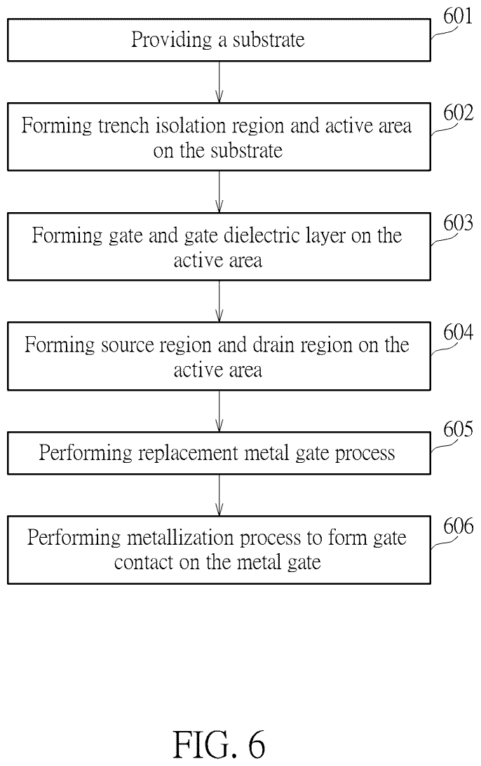

FIG. 6 is a flow chart illustrating a method of forming a transistor structure. As shown in FIG. 6, Step 601 is performed to provide a substrate, for example, a P-type silicon substrate. In Step 602, a shallow trench isolation process is performed to form a trench isolation region and an active area on the substrate. An ion implantation process may be performed to form an ion well and a lightly doped drain region in the substrate.

In Step 603, a polysilicon gate and a gate dielectric layer are formed on the active area, wherein the gate does not overlap with the trench isolation region. In some embodiments, the polysilicon gate has an H-shaped layout and has rounded corners when viewed from above (as shown in FIG. 4).

In Step 604, for example, an ion implantation process is performed to form a source region and a drain region in the active area. The polysilicon gate has a gate length parallel to the source-to-drain direction and a gate width smaller than the width of the active area.

In Step 605, a metal gate replacement process is performed to replace the polysilicon gate with a metal gate. In Step 606, a metallization process is performed. A dielectric layer is deposited on the metal gate, a gate contact is formed in the dielectric layer, and a source contact and a drain contact are formed on the source region and the drain region respectively. The gate contact is located directly above the channel region.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A transistor structure, comprising:
a substrate;
an active area defined by a trench isolation region on the substrate, wherein the active area comprises a source region, a drain region spaced apart from the source region, and a channel region between the source region and the drain region;
a gate disposed on the channel region, wherein the gate has a gate length that is in parallel with a source-to-drain direction and a gate width that is smaller than a width of the active area; and
a gate dielectric layer between the active area and the gate.

2. The transistor structure according to claim 1, wherein the gate does not overlap with the trench isolation region, and wherein the gate length is shorter than a length of the gate dielectric layer in the source-to-drain direction.

3. The transistor structure according to claim 1, wherein the gate is metal gate.

4. The transistor structure according to claim 1, wherein the gate has a first side edge distanced from an adjacent first side of the active area by a first margin.

5. The transistor structure according to claim 4, wherein the first margin is equal to or greater than 30 nm.

6. The transistor structure according to claim 4, wherein the gate has a second side edge that is opposite to the first side edge, and wherein the second side edge is distanced from an adjacent second side of the active area by a second margin.

7. The transistor structure according to claim 6, wherein the second margin is equal to or greater than 30 nm.

8. The transistor structure according to claim 1, wherein the gate has an H-shaped layout and the gate has rounded corners when viewed from above.

9. The transistor structure according to claim 1 further comprising:
at least one gate contact disposed on the gate, wherein the at least one gate contact is disposed directly above the channel region.

10. The transistor structure according to claim 1 further comprising:
a source contact disposed on the source region; and
a drain contact disposed on the drain region.

11. A method for forming a transistor structure, comprising:
providing a substrate;
forming an active area defined by a trench isolation region on the substrate, wherein the active area comprises a source region, a drain region spaced apart from the source region, and a channel region between the source region and the drain region;
forming a gate on the channel region, wherein the gate has a gate length that is in parallel with a source-to-drain direction and a gate width that is smaller than a width of the active area; and
forming a gate dielectric layer between the active area and the gate.

12. The method according to claim 11, wherein the gate does not overlap with the trench isolation region, and wherein the gate length is shorter than a length of the gate dielectric layer in the source-to-drain direction.

13. The method according to claim 11, wherein the gate is metal gate.

14. The method according to claim 11, wherein the gate has a first side edge distanced from an adjacent first side of the active area by a first margin.

15. The method according to claim 14, wherein the first margin is equal to or greater than 30 nm.

16. The method according to claim 14, wherein the gate has a second side edge that is opposite to the first side edge, and wherein the second side edge is distanced from an adjacent second side of the active area by a second margin.

17. The method according to claim 16, wherein the second margin is equal to or greater than 30 nm.

18. The method according to claim 11, wherein the gate has an H-shaped layout and the gate has rounded corners when viewed from above.

19. The method according to claim 11 further comprising:
forming at least one gate contact on the gate, wherein the at least one gate contact is disposed directly above the channel region.

20. The method according to claim 11 further comprising:
forming a source contact on the source region; and
forming a drain contact on the drain region.
